(19) United States
(12) Patent Application Publication
(10) Pub. No.: US 2025/0391657 A1
(43) Pub. Date: Dec. 25, 2025

(54) BASE SUBSTRATE

(71) Applicant: NGK INSULATORS, LTD., Nagoya-City (JP)

(72) Inventors: Kazuto MURAKAMI, Nagoya-Shi (JP); Morimichi WATANABE, Nagoya-Shi (JP)

(73) Assignee: NGK INSULATORS, LTD., Nagoya-City (JP)

(21) Appl. No.: 19/307,142

(22) Filed: Aug. 22, 2025

Related U.S. Application Data
(63) Continuation of application No. PCT/JP2024/005221, filed on Feb. 15, 2024.

(30) Foreign Application Priority Data
Mar. 23, 2023 (JP) 2023-046186

(51) Int. Cl. H01L 21/02

(52) U.S. Cl. CPC H01L 21/02433; H01L 21/0242

(57) ABSTRACT

There is provided a base substrate including an orientation layer used for crystal growth of a semiconductor film composed of α-Ga₂O₃ or an α-Ga₂O₃ solid solution. The orientation layer is composed of a material having a corundum-type crystal structure having an a-axis length and/or c-axis length larger than that of sapphire, and a plurality of microcrystals defined as crystal grains having a major axis length of 1 nm to 2 μm are present inside the orientation layer.

### CROSS-REFERENCE TO RELATED APPLICATIONS

This application is a continuation application of PCT/JP2024/005221 filed Feb. 15, 2024, which claims priority to Japanese Patent Application No. 2023-046186 filed Mar. 23, 2023, the entire contents all of which are incorporated herein by reference.

### BACKGROUND OF THE INVENTION

### 1. Field of the Invention

The present disclosure relates to a base substrate used for crystal growth of α-gallium oxide.

### 2. Description of the Related Art

In recent years, semiconductor devices using gallium nitride (GaN) have been put into practical use. For example, a device in which an n-type GaN layer, a multiple quantum well layer (MQW) in which a quantum well layer composed of an InGaN layer and a barrier layer composed of a GaN layer are alternately stacked, and a p-type GaN layer are sequentially stacked on a sapphire substrate has been mass-produced.

Further, research and development of corundum phase type α-gallium oxide (α-Ga₂O₃), which has the same crystal structure as sapphire, is being actively carried out. In fact, α-Ga₂O₃ has a large bandgap of 5.3 eV, and is expected as a material for power semiconductor elements. For example, Patent Literature 1 (JP2014-72533A) discloses an example in which α-Ga₂O₃ is formed as a semiconductor layer on a sapphire substrate in a semiconductor device formed of a base substrate having a corundum-type crystal structure, a semiconductor layer having a corundum-type crystal structure, and an insulating film having a corundum-type crystal structure. Further, Patent Literature 2 (JP2016-25256A) discloses a semiconductor device including an n-type semiconductor layer containing a crystalline oxide semiconductor having a corundum structure as a main component, a p-type semiconductor layer containing an inorganic compound having a hexagonal crystal structure as a main component, and an electrode, in which a diode is fabricated by forming α-Ga₂O₃ having a corundum structure which is a metastable phase as an n-type semiconductor layer and an α-Rh₂O₃ film having a hexagonal crystal structure as a p-type semiconductor layer on a c-plane sapphire substrate in an example.

It is known that, in these semiconductor devices, better characteristics can be obtained when there are fewer crystal defects. In particular, in a power semiconductor, the dielectric breakdown electric field characteristics depend on the number of crystal defects, and, therefore, it is desirable to significantly reduce crystal defects. Here, the crystal defects refer to threading edge dislocations, threading screw dislocations, threading mixed dislocations, and basal plane dislocations, and the crystal defect density is the total of the dislocation densities. However, since α-Ga₂O₃ is a metastable phase, a single-crystal substrate having few crystal defects has not been put into practical use, and α-Ga₂O₃ is generally formed by heteroepitaxial growth on a sapphire substrate or the like. In such a case, stress is sometimes applied into the semiconductor film due to a difference in lattice constants between α-Ga₂O₃ and sapphire to form a large number of crystal defects. For example, in a case where α-Ga₂O₃ is formed on a c-plane sapphire, the α-axis length (4.754 Å) of sapphire (α-Al₂O₃) and the a-axis length (4.983 Å) of α-Ga₂O₃ differ by about 5%, and this difference is the main cause of crystal defects.

As an approach for reducing the difference in lattice constants between the sapphire and α-Ga₂O₃, it is known to use an orientation layer containing a material having a corundum-type crystal structure having an a-axis length and/or c-axis length larger than that of sapphire. For example, Patent Literature 3 (JP7159449B) discloses a base substrate including an orientation layer used for crystal growth of a nitride or oxide of a Group 13 element, in which a top surface on a side used for the crystal growth of the orientation layer is composed of a material having a corundum-type crystal structure having an α-axis length and/or c-axis length larger than that of sapphire, and the orientation layer contains a solid solution containing two or more selected from the group consisting of α-Al₂O₃, α-Cr₂O₃, α-Fe₂O₃, α-Ti₂O₃, α-V₂O₃, and α-Rh₂O₃.

### CITATION LIST

### Patent Literature

Patent Literature 1: JP2014-72533A

Patent Literature 2: JP2016-25256A

Patent Literature 3: JP7159449A

### SUMMARY OF THE INVENTION

In a base substrate including an orientation layer as disclosed in Patent Literature 3, for example, the orientation layer is ground and polished to flatten and mirror-finish the top surface of the orientation layer. However, there is a problem that, in such a base substrate, in the step of grinding and polishing, chipping (defects such as chips and cracks) is likely to occur on the edge of the orientation layer, thereby reducing the yield.

The present inventors have now found that, when a base substrate including an orientation layer used for crystal growth of α-gallium oxide contains specific microcrystals inside the orientation layer, the lattice constant of the base substrate and that of α-Ga₂O₃ are matched, and chipping is less likely to occur by grinding and polishing.

Therefore, an object of the present disclosure is to provide a base substrate in which the lattice constant of the base substrate and that of α-Ga₂O₃ are matched, and chipping is less likely to occur by grinding and polishing.

The present disclosure provides the following aspects:

### [Aspect 1]

A base substrate comprising an orientation layer used for crystal growth of a semiconductor film composed of α-Ga₂O₃ or an α-Ga₂O₃ solid solution,
wherein the orientation layer is composed of a material having a corundum-type crystal structure having an a-axis length and/or c-axis length larger than that of sapphire, and
wherein a plurality of microcrystals defined as crystal grains having a major axis length of 1 nm to 2 μm are present inside the orientation layer.

### [Aspect 2]

The base substrate according to aspect 1, wherein the microcrystals have an average major axis length of 10 nm to 100 nm.

### [Aspect 3]

The base substrate according to aspect 1 or 2, wherein a number density of the microcrystals per unit area in the orientation layer is 1.00×10⁵ to 1.00×10¹²/cm².

### [Aspect 4]

The base substrate according to aspect 3, wherein the number density of the microcrystals per unit area in the orientation layer is 1.00×10¹⁰ to 1.00×10¹²/cm².

### [Aspect 5]

The base substrate according to any one of aspects 1 to 4, wherein the microcrystals contain one or more elements selected from the group consisting of Ti, Zr, Hf, Ge, Si, and Ce.

### [Aspect 6]

The base substrate according to aspect 5, wherein the microcrystals contain Ti.

### [Aspect 7]

The base substrate according to any one of aspects 1 to 6, wherein the microcrystals are needle crystals.

### [Aspect 8]

The base substrate according to any one of aspects 1 to 7 wherein the material having a corundum-type crystal structure contains α-Cr₂O₃ or an α-Cr₂O₃ solid solution.

### [Aspect 9]

The base substrate according to any one of aspects 1 to 8, further comprising a support substrate on a side opposite to a side used for crystal growth of the orientation layer.

### [Aspect 10]

The base substrate according to aspect 9, wherein the support substrate is a sapphire substrate.

### BRIEF DESCRIPTION OF THE DRAWINGS

FIG. 1 is a schematic cross-sectional view showing a configuration of an aerosol deposition (AD) apparatus.

FIG. 2 illustrates positions of a central point and four outer peripheral points on the top surface of an orientation layer.

FIG. 3 is an example of a TEM image obtained by observing an orientation layer with a transmission electron microscope (TEM) in Example 1.

### DETAILED DESCRIPTION OF THE INVENTION

### Base Substrate

The base substrate according to the present disclosure includes an orientation layer used for crystal growth of a semiconductor film composed of α-Ga₂O₃ or an α-Ga₂O₃ solid solution. The orientation layer is composed of a material having a corundum-type crystal structure having an a-axis length and/or c-axis length larger than that of sapphire. A plurality of microcrystals defined as crystal grains having a major axis length of 1 nm to 2 μm are present inside the orientation layer. In this manner, when the base substrate including an orientation layer used for crystal growth of α-gallium oxide contains specific microcrystals inside the orientation layer, the base substrate can be a base substrate in which the lattice constant of the base substrate and that of α-Ga₂O₃ are matched, and chipping is less likely to occur by grinding and polishing. That is, as described above, there is a problem that, in conventional base substrates, when the base substrate is ground and polished to flatten and mirror-finish the top surface, chipping (defects such as chips and cracks) is likely to occur on the edge, thereby reducing the yield. In this respect, according to the base substrate of the present disclosure, the problem can be conveniently solved.

A plurality of microcrystals defined as crystal grains having a major axis length of 1 nm to 2 μm are present inside the orientation layer. When the microcrystals are too large, the crystals sometimes degranulate to damage the polished surface, and, therefore, from the viewpoint of reducing occurrence of damage, it is preferable that the size of the microcrystals is small. Therefore, the average major axis length of the microcrystals is preferably 1 μm or less, more preferably 500 nm or less, and still more preferably 100 nm or less. There is no lower limit of the size of the microcrystals, but the average major axis length of the microcrystals is preferably 1 nm or more, and more preferably 10 nm or more. Therefore, the microcrystals have an average major axis length of preferably 1 nm to 1 μm, more preferably 10 nm to 1 μm, still more preferably 10 nm to 500 nm, and particularly preferably 10 nm to 100 nm. The size of the microcrystals can be measured using a scanning electron microscope (SEM), a transmission electron microscope (TEM), an optical microscope (OM), electron backscatter diffraction (EBSD), or the like. It is preferable that the microcrystals in the orientation layer are needle crystals.

From the viewpoint of reducing chipping, it is preferable that the number of the microcrystals in the orientation layer is large. Therefore, the number density of the microcrystals per unit area in the orientation layer is preferably 1.00×10^{5/}cm² or more, more preferably 1.0×10^{7/}cm² or more, still more preferably 1.0×10^{9/}cm² or more, and particularly preferably 1.00×10^{10/}cm² or more. There is no upper limit of the number density of the microcrystals, but the number density is preferably 1.00×10^{12/}cm² or less. Therefore, the number density of the microcrystals per unit area in the orientation layer is preferably 1.00×10⁵ to 1.00×10^{12/}cm², more preferably 1.0×10⁷ to 1.00×10^{12/}cm², still more preferably 1.0×10⁹ to 1.00×10^{12/}cm², and particularly preferably 1.00×10¹⁰ to 1.00×10^{12/}cm². The number density of the microcrystals can also be calculated using a scanning electron microscope (SEM), a transmission electron microscope (TEM), an optical microscope (OM), electron backscatter diffraction (EBSD), or the like.

The microcrystals in the orientation layer preferably contain one or more elements selected from the group consisting of Ti, Zr, Hf, Ge, Si, and Ce, and more preferably contain Ti. The element contained in the microcrystals can be identified using a known method, and, for example, energy dispersive X-ray spectroscopy (SEM-EDX), an electron probe micro analyzer (EPMA), a scanning transmission electron microscope (STEM-EDX), or time-of-flight secondary ion mass spectrometry (TOF-SIMS) can be used. A description that the microcrystals contain the above elements means that the above elements are detected by 0.1 at % or more in the microcrystals by any of the above methods. Therefore, the content of the above elements is preferably 0.1 at % or more based on the content of the all elements in the microcrystals. As the components of the microcrystals, besides the elements of Ti, Zr, Hf, Ge, Si, and Ce, components composing the orientation layer (for example, in a case where the material having a corundum-type crystal structure composing the orientation layer contains α-Cr₂O₃, Cr and O components) are preferably contained.

The orientation layer typically has a structure in which the crystal orientations are substantially aligned in the substantially normal direction. With such a configuration, it is possible to form a semiconductor layer having excellent quality, particularly excellent orientation, on the orientation layer. That is, when the semiconductor layer is formed on the orientation layer, the crystal orientation of the semiconductor layer generally follows the crystal orientation of the orientation layer. Therefore, when the base substrate includes an orientation layer, the semiconductor film can serve as an orientation film. The orientation layer may be a polycrystal, a mosaic crystal (a set of crystals of which crystal orientations are slightly deviated), or a single-crystal. In a case where the orientation layer is polycrystalline, it is preferably a biaxial orientation layer in which the twist direction (that is, the rotation direction about the substrate normal oriented substantially perpendicular to the substrate surface) is also substantially aligned.

The top surface of the orientation layer on the side used for crystal growth (hereinafter, may be simply referred to as “top surface” or “orientation layer top surface”) is composed of a material having a corundum-type crystal structure having an a-axis length and/or a c-axis length larger than that of sapphire (α-Al₂O₃). By controlling the lattice constant of the orientation layer in this way, it is possible to significantly reduce the crystal defects in the semiconductor layer formed on the orientation layer. That is, α-Ga₂O₃ constituting the semiconductor layer have a lattice constant larger than that of sapphire (α-Al₂O₃). In fact, as shown in Table 1 below, the lattice constant (a-axis length and c-axis length) of α-Ga₂O₃, which is an oxide of Group 13 elements, are larger than the lattice constant of α-Al₂O₃. Therefore, by controlling the lattice constant of the orientation layer to be larger than that of α-Al₂O₃, when the semiconductor layer is formed on the orientation layer, the mismatch of the lattice constant between the semiconductor layer and the orientation layer is decreased, and as a result, crystal defects in the semiconductor layer are reduced. For example, in a case where α-Ga₂O₃ is formed on the c-plane of sapphire, the lattice length (a-axis length) in the in-plane direction of α-Ga₂O₃ is larger than that of sapphire, and there is a mismatch of about 4.8%. Therefore, by controlling the a-axis length of the orientation layer to be larger than that of α-Al₂O₃, crystal defects in the α-Ga₂O₃ layer can be reduced. In a case where α-Ga₂O₃ is formed on the m-plane of sapphire, the lattice length (c-axis length and a-axis length) in the in-plane direction of α-Ga₂O₃ is larger than that of sapphire, and there is a mismatch of about 3.4% in the c-axis length and about 4.8% in the a-axis length. Therefore, by controlling the c-axis length and the a-axis length of the orientation layer to be larger than that of α-Al₂O₃, crystal defects in the α-Ga₂O₃ layer can be reduced. On the other hand, when semiconductor layers are formed directly on the sapphire substrate, stress is generated in the semiconductor layer due to the mismatch of lattice constants, and a large amount of crystal defects may be generated in the semiconductor layer.

TABLE 1
Lattice constants of Group 13 oxide

| | a-axis length (Å) | c-axis length (Å) |
|---|---|---|
| α-Ga₂O₃ | 4.983 | 13.433 |
| α-Al₂O₃ | 4.754 | 12.990 |
| α-Cr₂O₃ | 4.961 | 13.599 |
| α-Fe₂O₃ | 5.038 | 13.772 |
| α-Ti₂O₃ | 5.157 | 13.610 |
| α-V₂O₃ | 4.949 | 13.998 |
| α-Rh₂O₃ | 5.127 | 13.853 |
| α-In₂O₃ | 5.487 | 14.510 |

It is preferable that the entirety of the orientation layer is composed of a material having a corundum-type crystal structure. By doing so, it is possible to reduce crystal defects in the orientation layer and the semiconductor layer. It is desirable that the orientation layer is formed on the surface of the sapphire substrate. α-Al₂O₃ constituting the sapphire substrate has a corundum-type crystal structure, and since the orientation layer is composed of a material having a corundum-type crystal structure, the crystal structure can be made the same as that of the sapphire substrate, and as a result, the occurrence of crystal defects in the orientation layer due to crystal structure mismatch is suppressed. In this respect, it is preferable that the crystal defects in the orientation layer are reduced because the crystal defects in the semiconductor layer formed on the orientation layer are also reduced. This is because when a large number of crystal defects are present in the orientation layer, the crystal defects are also taken over to the semiconductor layer formed thereon, and as a result, crystal defects also occur in the semiconductor layer.

It is preferable that the material having a corundum-type crystal structure composing the orientation layer contains α-Cr₂O₃ or an α-Cr₂O₃ solid solution. As shown in Table 1, these materials have lattice constants (a-axis length and/or c-axis length) larger than that of α-Al₂O₃, and the lattice constants are relatively close to or coincide with those of α-Ga₂O₃, so that crystal defects in the semiconductor layer can be effectively suppressed. The solid solution may be a substitutional solid solution or an interstitial solid solution, but is preferably a substitutional solid solution. Incidentally, the orientation layer is composed of a material having a corundum-type crystal structure, but this does not preclude the inclusion of other trace components, which are, for example, microcrystals.

The a-axis length of the material having a corundum-type crystal structure on the top surface of the orientation layer on the side used for crystal growth is larger than 4.754 Å and 5.157 Å or less, and more preferably 4.850 to 5.000 Å, and still more preferably 4.900 to 5.000 Å. The c-axis length of the material having a corundum-type crystal structure on the top surface of the orientation layer on the side used for crystal growth is larger than 12.990 Å and 13.998 Å or less, and more preferably 13.000 to 13.800 Å, and still more preferably 13.400 to 13.600 Å. By controlling within such a range, the a-axis length and/or the c-axis length of the top surface of the orientation layer can be close to the lattice constant (a-axis length and/or c-axis length) of α-Ga₂O₃.

The thickness of the orientation layer is preferably 10 μm or more, and more preferably 40 μm or more. The upper limit of the thickness is not particularly limited, but is typically 1000 μm or less. In a case where the orientation layer is used as a stand-alone substrate, the thickness of the orientation layer may be even greater from the viewpoint of handleability, and the thickness may be, for example, 1 mm or more, and from the viewpoint of cost, the thickness may be, for example, 2 mm or less. The crystal defects on the top surface of the orientation layer can also be reduced by increasing the thickness of the orientation layer. When the orientation layer is formed on the sapphire substrate, the lattice constant of the sapphire substrate is slightly different from that of the orientation layer, and as a result, crystal defects are likely to occur at the interface between the sapphire substrate and the orientation layer, that is, in the lower portion of the orientation layer. However, by increasing the thickness of the orientation layer, it is possible to reduce the influence of such crystal defects generated in the lower portion of the orientation layer on the top surface of the orientation layer. The reason for this is not clear, but it is considered that the crystal defects generated in the lower portion of the orientation layer do not reach the top surface of the thick orientation layer and disappear. In addition, by increasing the thickness of the orientation layer, it is expected that the semiconductor layer can be separated after the semiconductor layer is formed over the orientation layer, and the base substrate can be reused. The crystal defect density on the top surface of the orientation layer is preferably 1.0×10^{8/}cm² or less, more preferably 1.0×10^{6/}cm² or less, and still more preferably 4.0×10^{3/}cm² or less, and there is no lower limit. Herein, the crystal defects refer to threading edge dislocations, threading screw dislocations, threading mixed dislocations, and basal plane dislocations, and the crystal defect density is the total of the dislocation densities. For example, when the material contains the threading edge dislocations of 3×10^{8/}cm², the threading screw dislocations of 6×10^{8/}cm², and the threading mixed dislocations of 4×10^{8/}cm², the crystal defect density becomes 1.3×10^{9/}cm². The basal plane dislocation is a problem in a case where the base substrate including the orientation layer has an off-angle, and is not a problem because the top surface of the orientation layer is not exposed in a case where there is no off-angle.

The orientation of the material composing the orientation layer is not particularly limited as long as it has an orientation property with respect to the surface of the base substrate, and is, for example, c-axis orientation, a-axis orientation, or m-axis orientation. By doing so, when the semiconductor layer is formed on the base substrate, the semiconductor film can be oriented in the c-axis orientation film, the a-axis orientation film, or the m-axis orientation film.

The orientation layer is preferably a heteroepitaxial growth layer. For example, in a case where the orientation layer is grown on the sapphire substrate, since both the sapphire substrate and the orientation layer have a corundum-type crystal structure, epitaxial growth in which the crystal plane of the orientation layer is arranged according to the crystal orientation of the sapphire substrate may occur during the heat treatment in a case where the lattice constants of the sapphire substrate and the orientation layer are close to each other. By epitaxially growing the orientation layer in this way, the orientation layer can inherit the high crystallinity and crystal orientation peculiar to the single-crystal of the sapphire substrate.

The arithmetic mean roughness Ra on the top surface of the orientation layer is preferably 1 nm or less, more preferably 0.5 nm or less, and still more preferably 0.2 nm or less. It is considered that the crystallinity of the semiconductor layer provided thereon is further improved by smoothing the top surface of the orientation layer in this way.

The base substrate has an area of preferably 20 cm² or more, more preferably 70 cm² or more, and still more preferably 170 cm² or more on one side thereof. By increasing the area of the base substrate in this way, it is possible to increase the area of the semiconductor layer formed on the substrate. Therefore, it is possible to obtain a large number of semiconductor elements from one semiconductor layer, and further reduction in production cost is expected. The upper limit of the size of the base substrate is not particularly limited, but is typically 700 cm² or less on one side.

The base substrate of the present disclosure preferably further includes a support substrate on the side opposite to the side used for crystal growth (that is, the bottom surface side) of the orientation layer. That is, the base substrate of the present disclosure may be a base substrate including a support substrate and an orientation layer provided on the support substrate. The support substrate is preferably a sapphire substrate or a corundum single-crystal such as Cr₂O₃, and particularly preferably a sapphire substrate. By using a corundum single-crystal as the support substrate, the orientation layer can also serve as a seed crystal for heteroepitaxial growth. Further, by forming the structure including the corundum single-crystal as described above, a semiconductor layer having excellent quality can be obtained. That is, the corundum single-crystal has characteristics such as excellent mechanical properties, thermal properties, and chemical stability. In particular, sapphire has a high thermal conductivity of 42 W/m·K at room temperature and is excellent in thermal conductivity. Therefore, by using a base substrate including a sapphire substrate, the thermal conductivity of the entire substrate can be improved. As a result, when the semiconductor layer is formed on the base substrate, it is expected that the temperature distribution in the substrate surface is prevented from becoming non-uniform, and the semiconductor layer having a uniform film thickness can be obtained. Further, a sapphire substrate having a large area is easily available, so that the overall cost can be reduced and a semiconductor layer having a large area can be obtained.

The sapphire substrate used as the support substrate may have any orientation plane. That is, for example, the sapphire substrate may have an a-plane, a c-plane, an r-plane, or an m-plane, or may have a predetermined off-angle with respect to these planes. Further, sapphire to which a dopant is added may be used in order to adjust the electrical characteristics. As such a dopant, a known dopant can be used.

A semiconductor layer composed of α-Ga₂O₃ can be formed using the orientation layer of the base substrate according to the present disclosure. The semiconductor layer can be formed by a known method, but is preferably formed by any of vapor phase film forming methods such as various CVD methods, an HVPE method, a sublimation method, an MBE method, a PLD method, and a sputtering method, and liquid phase film forming methods such as a hydrothermal method and an Na flux method. Examples of the CVD method include a thermal CVD method, a plasma CVD method, a mist CVD method, and an MO (metal organic) CVD method. Among these, the mist CVD method, the hydrothermal method, or the HVPE method is particularly preferable for forming the semiconductor layer composed of α-Ga₂O₃.

The base substrate of the present disclosure may be in the form of a self-standing substrate having an orientation layer alone, or may be in the form of a base substrate with a support substrate such as a sapphire substrate. Therefore, if desired, the orientation layer may ultimately be separated from the support substrate, such as a sapphire substrate. The separation of the support substrate may be performed by a known method and is not particularly limited. Examples thereof include a method of separating an orientation layer by applying mechanical impact, a method of separating an orientation layer by applying heat and utilizing thermal stress, a method of separating an orientation layer by applying vibration such as ultrasonic waves, a method of separating an orientation layer by etching an unnecessary portion, a method of separating an orientation layer by laser lift-off, and a method of separating an orientation layer by mechanical processing such as cutting or polishing. Further, in the case of heteroepitaxially growing the orientation layer on the sapphire substrate, the orientation layer may be installed on another support substrate after the sapphire substrate is separated. The material of the other support substrate is not particularly limited, but a suitable material may be selected from the viewpoint of material properties. For example, from the viewpoint of thermal conductivity, a metal substrate or a substrate made of Cu or the like, a ceramic substrate made of SiC, AlN or the like, or the like may be used.

### Production Method

The base substrate of the present disclosure can be preferably produced by (a) providing a sapphire substrate, (b) preparing an orientation precursor layer containing an element composing the microcrystals, (c) subjecting the orientation precursor layer to heat treatment on the sapphire substrate to convert at least a portion near the sapphire substrate into an orientation layer, and (d) subjecting the orientation layer to processing such as grinding or polishing to smooth the top surface of the orientation layer. This orientation precursor layer becomes an orientation layer by heat treatment and contains a material having a corundum-type crystal structure having an a-axis length and/or c-axis length larger than that of sapphire or a material capable of having a corundum-type crystal structure having an a-axis length and/or c-axis length larger than that of sapphire by heat treatment to be described later. According to such a production method, the growth of the orientation layer can be promoted by using the sapphire substrate as a seed crystal. That is, the high crystallinity and crystal orientation peculiar to the single-crystal of the sapphire substrate are inherited by the orientation layer.

### (a) Provision of Sapphire Substrate

To prepare a base substrate, first, a sapphire substrate is provided. The sapphire substrate used may have any orientation plane. That is, for example, the sapphire substrate may have an a-plane, a c-plane, an r-plane, or an m-plane, or may have a predetermined off-angle with respect to these planes. For example, in a case where a c-plane sapphire is used, since the c-axis is oriented with respect to the surface, it is possible to easily heteroepitaxially grow a c-axis oriented orientation layer thereon. A sapphire substrate to which a dopant is added may also be used to adjust electrical properties. As such a dopant, a known dopant can be used.

### (b) Preparation of Orientation Precursor Layer

An orientation precursor layer containing a material having a corundum-type crystal structure having an a-axis length and/or c-axis length larger than that of sapphire or a material capable of having a corundum-type crystal structure having an a-axis length and/or c-axis length larger than that of sapphire by heat treatment is prepared. The orientation precursor layer preferably contains, as a material composing the microcrystals, one or more elements selected from the group consisting of Ti, Zr, Hf, Ge, Si, and Ce, and these elements are preferably contained in the orientation precursor layer in the form of a metal simple substance or in the form of a compound other than an oxide (such as a nitride). The method for forming the orientation precursor layer is not particularly limited, and a known method can be adopted. Examples of the method for forming the orientation precursor layer include an aerosol deposition (AD) method, a hydrothermal method, a sputtering method, an evaporation method, various chemical vapor deposition (CVD) methods, an HVPE method, a PLD method, a chemical vapor transport (CVT) method, and a sublimation method. Examples of the CVD method include a thermal CVD method, a plasma CVD method, a mist CVD method, and an MO (metal organic) CVD method. Alternatively, a method may be used in which a molded body of the orientation precursor is prepared in advance and the molded body is placed on a sapphire substrate. Such a molded body can be produced by molding the material of the orientation precursor by a method such as tape casting or press molding. Further, it is also possible to use a method in which a polycrystal prepared in advance by various CVD methods, sintering, or the like is used as the orientation precursor layer and is placed on a sapphire substrate.

However, AD methods, various CVD methods, or sputtering methods are preferred. By using these methods, a dense orientation precursor layer can be formed in a relatively short time, and heteroepitaxial growth using a sapphire substrate as a seed crystal can be easily caused. In particular, the AD method does not require a high vacuum process and has a relatively high film formation rate, and is therefore preferable in terms of production cost. In the case of using a sputtering method, a film can be formed using a target of the same material as that of the orientation precursor layer, but a reactive sputtering method in which a film is formed in an oxygen atmosphere using a metal target can also be used. A method of placing a molded body prepared in advance on sapphire is also preferable as a simple method, but since the orientation precursor layer is not dense, a process of densification is required in the heat treatment step described later. In the method of using a polycrystalline prepared in advance as an orientation precursor layer, two steps of a step of preparing a polycrystalline body and a step of performing heat treatment on a sapphire substrate are required. Further, in order to improve the adhesion between the polycrystal and the sapphire substrate, it is necessary to take measures such as keeping the surface of the polycrystal sufficiently smooth. Although known conditions can be used for any of the methods, a method of directly forming an orientation precursor layer using an AD method and a method of placing a molded body prepared in advance on a sapphire substrate will be described below.

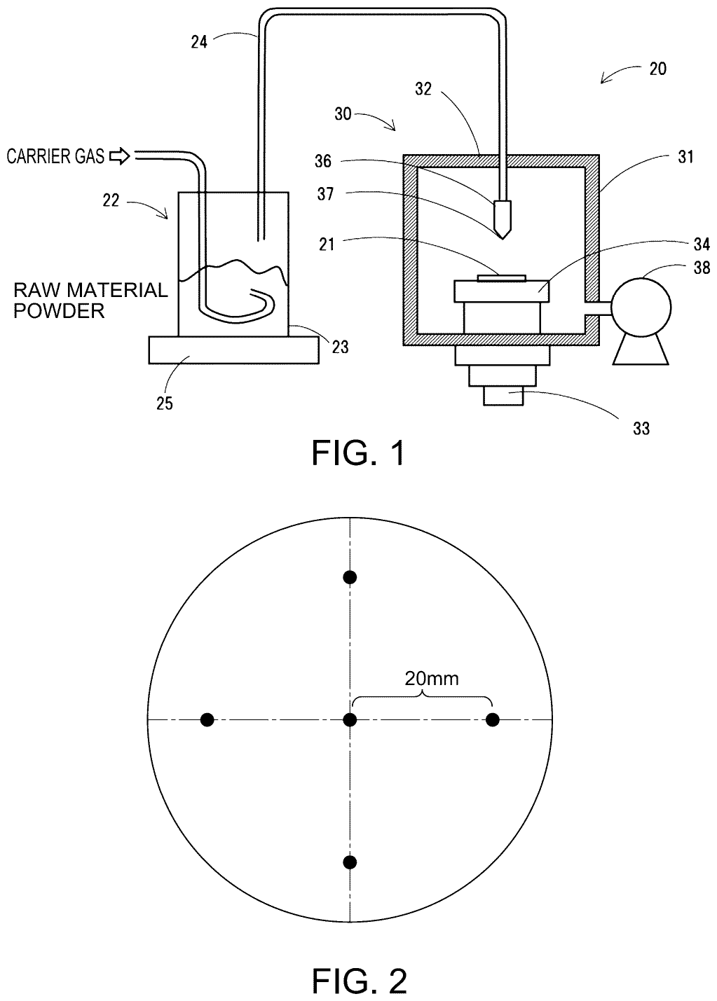

The AD method is a technique for forming a film by mixing fine particles or a fine particle raw material with a gas to form an aerosol, and impacting the aerosol on a substrate by injecting the aerosol at a high speed from a nozzle, and has a feature of forming a film densified at ordinary temperature. FIG. 1 shows an example of a film forming apparatus (aerosol deposition (AD) apparatus) used in such an AD method. The film forming apparatus 20 shown in FIG. 1 is configured as an apparatus used in an AD method in which a raw material powder is injected onto a substrate in an atmosphere having a pressure lower than atmospheric pressure. The film forming apparatus 20 includes an aerosol generating unit 22 that generates an aerosol of raw material powder containing raw material components, and a film forming unit 30 that forms a film containing the raw material components by injecting the raw material powder onto the sapphire substrate 21. The aerosol generating unit 22 includes an aerosol generating chamber 23 that stores raw material powder and receives a carrier gas supply from a gas cylinder (not shown) to generate an aerosol, and a raw material supply pipe 24 that supplies the generated aerosol to the film forming unit 30, and a vibrator 25 that applies vibration at frequencies of 10 to 100 Hz to the aerosol generating chamber 23 and the aerosol therein. The film forming unit 30 has a film forming chamber 32 that injects aerosols onto the sapphire substrate 21, a substrate holder 34 that is disposed inside the film forming chamber 32 and fixes the sapphire substrate 21, and an X-Y stage 33 that moves the substrate holder 34 in the X-Y axis direction. Further, the film forming unit 30 includes an injection nozzle 36 in which a slit 37 is formed at a tip thereof to inject aerosol into the sapphire substrate 21, and a vacuum pump 38 for reducing the pressure in the film forming chamber 32.

It is known that the AD method can control a film thickness, a film quality, and the like according to film forming conditions. For example, the form of the AD film is easily affected by the collision rate of the raw material powder to the substrate, the particle size of the raw material powder, the aggregated state of the raw material powder in the aerosol, the injection amount per unit time, and the like. The collision rate of the raw material powder with the substrate is affected by the differential pressure between the film forming chamber 32 and the injection nozzle 36, the opening area of the injection nozzle, and the like. If appropriate conditions are not used, the coating may become a green compact or generate pores, so it is desirable to appropriately control these factors.

In a case where a molded body in which the orientation precursor layer is prepared in advance is used, the raw material powder of the orientation precursor can be molded to prepare the molded body. For example, in a case where press molding is used, the orientation precursor layer is a press molded body. The press molded body can be prepared by press-molding the raw material powder of the orientation precursor based on a known method, and may be prepared, for example, by placing the raw material powder in a mold and pressing the raw material powder at pressures of preferably 100 to 400 kgf/cm², and more preferably 150 to 300 kgf/cm². The molding method is not particularly limited, and in addition to press molding, tape casting, slip casting, extrusion molding, doctor blade method, and any combination thereof can be used. For example, in the case of using tape casting, it is preferable that additives such as a binder, a plasticizer, a dispersant, and a dispersion medium are appropriately added to the raw material powder to form a slurry, and the slurry is discharged and molded into a sheet shape by passing through a slit-shaped thin discharge port. The thickness of the molded body formed into a sheet is not limited, but is preferably 5 to 500 μm from the viewpoint of handling. Further, in a case where a thick orientation precursor layer is required, a large number of these sheet molded bodies may be stacked and used as a desired thickness.

In these molded bodies, the portion near the sapphire substrate becomes an orientation layer by the subsequent heat treatment on the sapphire substrate. As described above, in such a method, it is necessary to sinter and densify the molded body in the heat treatment step described later. Therefore, the molded body may contain trace components such as a sintering aid in addition to the material having or resulting in a corundum-type crystal structure.

### (c) Heat Treatment of Orientation Precursor Layer on Sapphire Substrate

A heat treatment is performed on the sapphire substrate on which the orientation precursor layer is formed at a temperature of 1000° C. or more. By this heat treatment, at least a portion of the orientation precursor layer near the sapphire substrate can be converted into a dense orientation layer. Further, this heat treatment enables heteroepitaxial growth of the orientation layer. That is, by forming the orientation layer with a material having a corundum-type crystal structure, heteroepitaxial growth occurs in which the material having a corundum-type crystal structure crystal grows using a sapphire substrate as a seed crystal during heat treatment. At that time, the crystals are rearranged, and the crystals are arranged according to the crystal plane of the sapphire substrate. As a result, the crystal axes of the sapphire substrate and the orientation layer can be aligned. For example, when a c-plane sapphire substrate is used, both the sapphire substrate and the orientation layer can be c-axis oriented with respect to the surface of the base substrate.

It is known that methods such as various CVD methods, a sputtering method, an HVPE method, a PLD method, a CVT method, and a sublimation method may cause heteroepitaxial growth on a sapphire substrate without heat treatment at 1000° C. or more. However, it is preferable that the orientation precursor layer is in a non-oriented state, that is, amorphous or non-oriented polycrystalline, at the time of preparation thereof, and the crystal rearrangement is caused by using sapphire as a seed crystal at the time of the heat treatment step. By doing so, it is possible to effectively reduce the crystal defects that reach the top surface of the orientation layer. The reason for this is not clear, but it is considered that the crystal defects generated in the lower portion of the orientation layer are likely to be annihilated.

A method of the heat treatment is not particularly limited as long as a corundum-type crystal structure is obtained and heteroepitaxial growth using a sapphire substrate as a seed occurs, and can be performed in a known heat treatment furnace such as a tubular furnace or a hot plate. Further, in addition to the heat treatment under normal pressure (without pressing), a heat treatment under pressure such as hot pressing or HIP, or a combination of a heat treatment under normal pressure and a heat treatment under pressure can also be used. The heat treatment conditions can be appropriately selected depending on the material used for the orientation layer. For example, the atmosphere of the heat treatment can be selected from the air, vacuum, nitrogen and inert gas atmosphere. The preferred heat treatment temperature also varies depending on the material used for the orientation layer, but is preferably 1000 to 2000° C., and more preferably 1200 to 2000° C., for example. The heat treatment temperature and the retention time are related to the thickness of the orientation layer formed by heteroepitaxial growth and the like, and can be appropriately adjusted depending on the kind of the material, the thickness of the target orientation layer, and the like. However, in the case of using molded body prepared in advance is used as the orientation precursor layer, it is necessary to perform sintering and densification during heat treatment, and normal pressure firing at a high temperature, hot pressing, HIP, or a combination thereof is suitable. For example, when using a hot press, the surface pressure is preferably 50 kgf/cm2 or more, more preferably 100 kgf/cm2 or more, particularly preferably 200 kgf/cm2 or more, the upper limit is not particularly limited. The firing temperature is also not particularly limited as long as sintering, densification, and heteroepitaxial growth occur, but is preferably 1000° C. or more, more preferably 1200° C. or more, still more preferably 1400° C. or more, and particularly preferably 1600° C. or more. The firing atmosphere can also be selected from atmosphere, vacuum, nitrogen and an inert gas atmosphere. As the firing jig such as a mold, those made of graphite or alumina can be used.

### (d) Exposure of Surface of Orientation Layer

On the orientation layer formed near the sapphire substrate by the heat treatment, an orientation precursor layer or a surface layer having poor orientation or no orientation may exist or remain. In this case, it is preferable that the surface derived from the orientation precursor layer is subjected to processing such as grinding or polishing to expose the surface of the orientation layer. By doing so, a material having excellent orientation is exposed on the surface of the orientation layer, so that the semiconductor layer can be effectively epitaxially grown on the material. The method for removing the orientation precursor layer and the surface layer is not particularly limited, and examples thereof include a method for grinding and polishing and a method for ion beam milling. The surface of the orientation layer is preferably polished by lapping using abrasive grains or chemical mechanical polishing (CMP).

Specific examples of the method for grinding and polishing of the orientation layer include the following methods. That is, three base substrates having the same size are fixed to a ceramic surface plate at three locations, the surface on the side of the film-forming surface of the base substrate is ground by grinder processing using a grinding stone having a grit size of #320 to #2000 until the orientation layer was exposed. Thereafter, the plate surface of the orientation layer is further smoothed by lapping using diamond abrasive grains. At this time, lapping is performed while gradually reducing the size of the diamond abrasive grains, thereby improving the flatness of the plate surface. Thereafter, the top surface of the orientation layer is subjected to mirror finishing by chemical mechanical polishing (CMP) using colloidal silica to obtain a composite base substrate including an orientation layer on a sapphire substrate. At this time, polishing is preferably performed until the arithmetical mean roughness Ra of the top surface of the orientation layer after processing reaches 0.2 nm or less. The arithmetical mean roughness Ra of the top surface of the orientation layer can be checked using a commercially available surface roughness meter.

### EXAMPLES

The present disclosure will be described in more detail with reference to the following examples.

### Example 1

### (1) Preparation of Composite Base Substrate

### (1a) Preparation of Orientation Precursor Layer

As raw material powders, commercially available Cr₂O₃ powder (volume average particle size 3 μm) and commercially available TiN powder (volume average particle size 0.8 μm) were provided. By using a powder in which 1.5 parts by weight of the TiN powder and 100 parts by weight of the Cr₂O₃ powder were mixed together with a pot mill for 48 hours and sapphire (diameter 50.8 mm (2 inches), thickness 0.43 mm, c-plane, off-angle 0.3°) as the substrate, an AD film (orientation precursor layer) containing Cr₂O₃ as a main component was formed on a seed substrate (sapphire substrate) by an aerosol deposition (AD) apparatus 20 illustrated in FIG. 1. The configuration of the aerosol deposition (AD) apparatus 20 is as described above.

The AD film formation conditions were as follows. That is, Ar was used as a carrier gas, and a ceramic nozzle having a slit having a long side of 5 mm and a short side of 0.3 mm was used. The scanning conditions of the nozzle were to move 55 mm in the direction perpendicular to the long side of the slit and forward, to move 5 mm in the long side direction of the slit, to move 55 mm in the direction perpendicular to the long side of the slit and backward, and to move 5 mm in the long side direction of the slit and opposite to the initial position, repeatedly at a scanning speed of 0.5 mm/s, and at the time of 55 mm movement from the initial position in the long side direction of the slit, scanning was performed in the direction opposite to the previous direction, and the nozzle returned to the initial position. This was defined as one cycle, and repeated for 500 cycles. In one cycle of film formation at room temperature, the set pressure of the transport gas was adjusted to 0.07 MPa, the flow rate was adjusted to 8 L/min, and the pressure in the chamber was adjusted to 100 Pa or less. The AD film (orientation precursor layer) thus formed had a thickness of 120 μm.

### (1b) Heat Treatment of Orientation Precursor Layer

The sapphire substrate on which the AD film (orientation precursor layer) was formed was taken out from the AD apparatus and annealed at 1700° C. for 4 hours in a nitrogen atmosphere.

### (1c) Grinding and Polishing

The obtained substrate was fixed to a ceramic surface plate, the surface on the side derived from the AD film was ground using a grinding stone having a grit size from #320 to #2000 or less until the orientation layer was exposed, and then the plate surface was further smoothed by lapping using diamond abrasive grains. At this time, lapping was performed while gradually reducing the size of the diamond abrasive grains from 3 μm to 0.5 μm, thereby improving the flatness of the plate surface. Thereafter, mirror finishing was performed by chemical mechanical polishing (CMP) using colloidal silica to obtain a composite base substrate having an orientation layer on a sapphire substrate. The arithmetical mean roughness Ra of the orientation layer top surfaces after processing was 0.1 nm, the amount of grinding and polishing was 70 μm, and the thicknesses of the composite base substrate after polishing was 0.48 mm. The surface on the side on which the AD film is formed is referred to as a “top surface”. 101 composite base substrates were prepared by repeating the steps (1a) to (1c) above.

### (2) Evaluation of Orientation Layer

### (2a) Surface EDX

The composition of the substrate top surface on which the orientation layer was exposed was analyzed using an energy dispersive X-ray analyzer (EDX). As a result, Cr and O as main components and Ti as a trace component were detected, and it was found that the orientation layer contained Cr oxide as a main phase. In addition, it was presumed that the orientation layer contained microcrystals containing Ti.

### (2b) Surface EBSD

An SEM (SU-5000, manufactured by Hitachi High-Technologies Corporation) equipped with an electron backscatter diffraction apparatus (EBSD) (Nordlys Nano, manufactured by Oxford Instruments Inc.) was used to perform reverse pole figure orientation mapping of the surface of the orientation layer containing the Cr oxide as a main phase in a field of view of 500 μm×500 μm.

### <EBSD Measurement Conditions>

Acceleration voltage: 15 kV
Spot intensity: 70
Working distance: 22.5 mm
Step size: 0.5 μm
Sample tilt angle: 70°
Measurement program: Aztec (version 3.3)

From the obtained reverse pole figure orientation mapping, it was found that the top surface of the orientation layer containing Cr oxide as a main phase had a biaxially oriented corundum-type crystal structure in which the top surface of the orientation layer was c-axis oriented in the substrate normal direction and was also oriented in the in-plane direction. From these, it was shown that the orientation layer containing α-Cr₂O₃ as a main phase was formed on the substrate top surface.

### (2c) Plane TEM and STEM-EDX of Orientation Layer

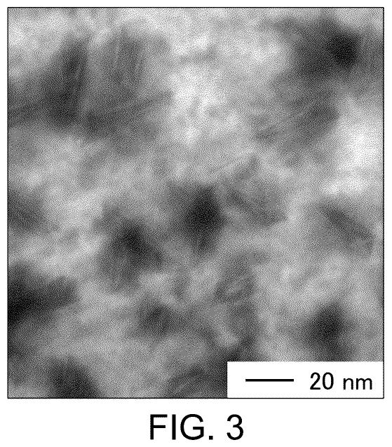

Plane TEM observation (plan view) was performed to evaluate the microstructure of the orientation layer. Five samples for TEM observation were cut out from five locations in a region having a depth of about 10 μm from the top surface of the orientation layer by performing processing using a focused ion beam (FIB) so that the sample thickness around the measurement field of view was about 400 nm. As illustrated in FIG. 2, the sampling locations were the central point of the substrate and four outer peripheral points on two straight lines intersecting at a right angle at the central point drawn on the substrate, the distance between the central point and each outer peripheral points being about 20 mm.

The obtained sections were subjected to TEM observation at an acceleration voltage of 300 kV using a transmission electron microscope (H-9000UHR-II manufactured by Hitachi). Actually, two fields of view in each section that had been cut out (10 fields of view in total) of TEM images each having a measurement field of view of about 10 μm×10 μm to 161 nm×161 nm were observed. As a result, needle microcrystals were observed in the TEM image obtained in the field of view of 161 nm×161 nm, and the number of the observed microcrystals was 20 to 30 in each field of view. At this time, the number of microcrystals was determined by counting crystal grains having a major axis length of 1 nm to 2 μm. An example of the obtained TEM image is illustrated in FIG. 3. The major axis lengths of the microcrystals observed by TEM observation were measured to calculate the average major axis length of the 10 fields of view. In addition, the total number of microcrystals observed by TEM observation in the 10 fields of view was divided by the area of the total observation fields of view to calculate the number density of microcrystals per unit area (number/cm²). The results are shown in Table 2. In addition, each section was subjected to EDX measurement using a scanning transmission electron microscope (JEM-ARM200F Dual-X manufactured by JEOL, EDX: JED-2300 manufactured by JEOL) at an acceleration voltage of 200 kV. As a result of spot analysis with an electron beam with a beam spot size of about 0.2 nm in diameter, 2.71 at % of Ti was detected in the microcrystals, and it was found that Ti was concentrated in the microcrystals from mapping measurement.

### (3) Evaluation of Composite Base Substrate

### (3a) Evaluation of Chipping

Among the 101 composite base substrates prepared in the above (1), 100 substrates that were not used for the evaluation of the orientation layer in the above (2) were used to evaluate the chipping state of the edge of the orientation layer. Actually, the edge of the orientation layer after grinding and polishing was observed with an optical microscope at 50× magnification, and a chip having a longest side of 50 μm or more was determined as chipping, and presence or absence of the chipping was checked. Substrates without chipping were determined to be acceptable, and substrates having chipping were determined to be unacceptable, and the number of acceptable substrates was calculated. The number of acceptable substrates was divided by the total number of substrates ground and polished, which was 100, to calculate a non-defective rate R1. The non-defective rate R1 is preferably 0.75 or more, and more preferably 0.85 or more. The results are shown in Table 2.

### (3b) Evaluation of Damage

Among the 101 composite base substrates prepared in the above (1), 100 substrates that were not used for the evaluation of the orientation layer in the above (2) were used to evaluate the state of damage on the top surface of the orientation layer. Actually, the top surface of the orientation layer after grinding and polishing was observed with an optical microscope at 50× magnification, and presence or absence of damage was checked. Substrates having 3 or less damaged parts visually observed were determined to be acceptable, and substrates having 4 or more damaged parts visually observed were determined to be unacceptable, and the number of acceptable substrates was calculated. The number of acceptable substrates was divided by the total number of substrates ground and polished, which was 100, to calculate a non-defective rate R2. The non-defective rate R2 is preferably 0.75 or more, and more preferably 0.95 or more. The results are shown in Table 2.

### Examples 2 to 4

A composite base substrate was prepared in the same manner as in Example 1 and the orientation layer and the composite base substrate were evaluated except that the feeding amount of the TiN powder in the above (1a) was changed to the amount shown in Table 2. The results are shown in Table 2. It was found that, by EDX measurement and EBSD measurement, the orientation layer contained α-Cr₂O₃ as a main phase and the top surface thereof had a biaxially oriented corundum-type crystal structure in which the top surface was c-axis oriented in the substrate normal direction and was also oriented in the in-plane direction. In addition, it was found that, by STEM-EDX measurement, the orientation layer contained microcrystals containing Ti.

### Example 5

A composite base substrate was prepared in the same manner as in Example 1 and the orientation layer and the composite base substrate were evaluated except that the volume average particle size of the TiN powder in the above (1a) was changed to the size shown in Table 2, and the heat treatment temperature of the orientation precursor layer in the above (1b) was changed to the temperature shown in Table 2. The results are shown in Table 2. It was found that, by EDX measurement and EBSD measurement, the orientation layer contained α-Cr₂O₃ as a main phase and the top surface thereof had a biaxially oriented corundum-type crystal structure in which the top surface was c-axis oriented in the substrate normal direction and was also oriented in the in-plane direction. In addition, it was found that, by STEM-EDX measurement, the orientation layer contained microcrystals containing Ti.

### Examples 6 to 8

A composite base substrate was prepared in the same manner as in Example 1 and the orientation layer and the composite base substrate were evaluated except that the feeding amount and the volume average particle size of the TiN powder in the above (1a) were changed to the amount and the size, respectively, shown in Table 2, and the heat treatment temperature of the orientation precursor layer in the above (1b) was changed to the temperature shown in Table 2. The results are shown in Table 2. It was found that, by EDX measurement and EBSD measurement, the orientation layer contained α-Cr₂O₃ as a main phase and the top surface thereof had a biaxially oriented corundum-type crystal structure in which the top surface was c-axis oriented in the substrate normal direction and was also oriented in the in-plane direction. In addition, it was found that, by STEM-EDX measurement, the orientation layer contained microcrystals containing Ti.

### Example 9

A composite base substrate was prepared in the same manner as in Example 1 and the orientation layer and the composite base substrate were evaluated except that the volume average particle size of the TiN powder and the mixing time of the raw material powder in the above (1a) were changed to the size and the time, respectively, shown in Table 2, and the heat treatment temperature of the orientation precursor layer in the above (1b) was changed to the temperature shown in Table 2. The results are shown in Table 2. It was found that, by EDX measurement and EBSD measurement, the orientation layer contained α-Cr₂O₃ as a main phase and the top surface thereof had a biaxially oriented corundum-type crystal structure in which the top surface was c-axis oriented in the substrate normal direction and was also oriented in the in-plane direction. In addition, it was found that, by STEM-EDX measurement, the orientation layer contained microcrystals containing Ti.

### Examples 10 to 12

A composite base substrate was prepared in the same manner as in Example 1 and the orientation layer and the composite base substrate were evaluated except that the feeding amount and the volume average particle size of the TiN powder and the mixing time of the raw material powder in the above (1a) were changed to the amount, the size, and the time, respectively, shown in Table 2, and the heat treatment temperature of the orientation precursor layer in the above (1b) was changed to the temperature shown in Table 2. The results are shown in Table 2. It was found that, by EDX measurement and EBSD measurement, the orientation layer contained α-Cr₂O₃ as a main phase and the top surface thereof had a biaxially oriented corundum-type crystal structure in which the top surface was c-axis oriented in the substrate normal direction and was also oriented in the in-plane direction. In addition, it was found that, by STEM-EDX measurement, the orientation layer contained microcrystals containing Ti.

### Example 13

A composite base substrate was prepared in the same manner as in Example 1 and the orientation layer and the composite base substrate were evaluated except that TiC_{0.5}N_{0.5} powder was added instead of the TiN powder in the above (1a); the volume average particle size thereof and the mixing time of the raw material powder in the above (1a) were changed to the size and the time, respectively, shown in Table 2; and the heat treatment temperature of the orientation precursor layer in the above (1b) was changed to the temperature shown in Table 2. The results are shown in Table 2. It was found that, by EDX measurement and EBSD measurement, the orientation layer contained α-Cr₂O₃ as a main phase and the top surface thereof had a biaxially oriented corundum-type crystal structure in which the top surface was c-axis oriented in the substrate normal direction and was also oriented in the in-plane direction. In addition, it was found that, by STEM-EDX measurement, the orientation layer contained microcrystals containing Ti.

### Examples 14 to 16

A composite base substrate was prepared in the same manner as in Example 1 and the orientation layer and the composite base substrate were evaluated except that TiC_{0.5}N_{0.5} powder was added instead of the TiN powder in the above (1a); the feeding amount and the volume average particle size thereof and the mixing time of the raw material powder in the above (1a) were changed to the amount, the size, and the time, respectively, shown in Table 2; and the heat treatment temperature of the orientation precursor layer in the above (1b) was changed to the temperature shown in Table 2. The results are shown in Table 2. It was found that, by EDX measurement and EBSD measurement, the orientation layer contained α-Cr₂O₃ as a main phase and the top surface thereof had a biaxially oriented corundum-type crystal structure in which the top surface was c-axis oriented in the substrate normal direction and was also oriented in the in-plane direction. In addition, it was found that, by STEM-EDX measurement, the orientation layer contained microcrystals containing Ti.

### Example 17 (Comparison)

A composite base substrate was prepared in the same manner as in Example 1 and the orientation layer and the composite base substrate were evaluated except that the TiN powder or the TiC_{0.5}N_{0.5} powder was not added in the (1a), and a commercially available Cr₂O₃ powder was used as a raw material powder. The results are shown in Table 2. No microcrystal was observed even when the orientation layer was subjected to TEM observation.

TABLE 2

| | Feeding amount | | | | | | | |
|---|---|---|---|---|---|---|---|---|
| | of TiN powder | Volume | | | | | | |
| | or TiC_{0.5}N_{0.5} | average | | | | | | |
| | powder based | particle | | | | | | |
| | on 100 parts | size of | | | | | | |
| | by weight | TiN | Mixing | Heat treatment | | | | |
| | of Cr₂O₃ | powder or | time of | temperature of | Average major | Number | | |
| | powder | TiC_{0.5}N_{0.5} | raw | orientation | axis length of | density of | Non- | Non- |
| | (parts by | powder | material | precursor | microcrystals | microcrystals | defective | defective |
| | weight) | (μm) | powder (h) | layer (° C.) | (nm) | (number/cm²) | rate R1 | rate R2 |
| Ex. 1 | 1.50 | 0.8 | 48 | 1700 | 18 | 1.04 × 10¹¹ | 0.97 | 0.95 |
| Ex. 2 | 2.25 | 0.8 | 48 | 1700 | 24 | 1.56 × 10¹¹ | 0.98 | 0.97 |
| Ex. 3 | 3.00 | 0.8 | 48 | 1700 | 26 | 2.08 × 10¹¹ | 0.99 | 0.99 |
| Ex. 4 | 3.75 | 0.8 | 48 | 1700 | 30 | 2.61 × 10¹¹ | 1.00 | 1.00 |
| Ex. 5 | 1.50 | 2.5 | 48 | 1600 | 105 | 1.07 × 10⁹ | 0.90 | 0.89 |
| Ex. 6 | 2.25 | 2.5 | 48 | 1600 | 112 | 1.47 × 10⁹ | 0.91 | 0.90 |
| Ex. 7 | 3.00 | 2.5 | 48 | 1600 | 120 | 2.11 × 10⁹ | 0.92 | 0.91 |
| Ex. 8 | 3.75 | 2.5 | 48 | 1600 | 127 | 2.49 × 10⁹ | 0.93 | 0.92 |
| Ex. 9 | 1.50 | 2.5 | 16 | 1550 | 501 | 1.01 × 10⁷ | 0.83 | 0.82 |
| Ex. 10 | 2.25 | 2.5 | 16 | 1550 | 545 | 1.56 × 10⁷ | 0.84 | 0.84 |
| Ex. 11 | 3.00 | 2.5 | 16 | 1550 | 561 | 2.02 × 10⁷ | 0.85 | 0.85 |
| Ex. 12 | 3.75 | 2.5 | 16 | 1550 | 609 | 2.48 × 10⁷ | 0.86 | 0.86 |
| Ex. 13 | 1.50 | 3.0 | 8 | 1500 | 1002 | 1.10 × 10⁵ | 0.77 | 0.76 |
| Ex. 14 | 2.25 | 3.0 | 8 | 1500 | 1048 | 1.61 × 10⁵ | 0.78 | 0.77 |
| Ex. 15 | 3.00 | 3.0 | 8 | 1500 | 1074 | 2.13 × 10⁵ | 0.79 | 0.78 |
| Ex. 16 | 3.75 | 3.0 | 8 | 1500 | 1113 | 2.44 × 10⁵ | 0.80 | 0.79 |
| Ex. 17* | — | — | — | 1700 | — | — | 0.70 | 0.72 |

*indicates a Comparative Example.

What is claimed is:

1. A base substrate comprising an orientation layer used for crystal growth of a semiconductor film composed of α-Ga₂O₃ or an α-Ga₂O₃ solid solution,
wherein the orientation layer is composed of a material having a corundum-type crystal structure having an a-axis length and/or c-axis length larger than that of sapphire, and
wherein a plurality of microcrystals defined as crystal grains having a major axis length of 1 nm to 2 μm are present inside the orientation layer.

2. The base substrate according to claim 1, wherein the microcrystals have an average major axis length of 10 nm to 100 nm.

3. The base substrate according to claim 1, wherein a number density of the microcrystals per unit area in the orientation layer is 1.00×10⁵ to 1.00×10^{12/}cm².

4. The base substrate according to claim 3, wherein the number density of the microcrystals per unit area in the orientation layer is 1.00×10¹⁰ to 1.00×10^{12/}cm².

5. The base substrate according to claim 1, wherein the microcrystals contain one or more elements selected from the group consisting of Ti, Zr, Hf, Ge, Si, and Ce.

6. The base substrate according to claim 5, wherein the microcrystals contain Ti.

7. The base substrate according to claim 1, wherein the microcrystals are needle crystals.

8. The base substrate according to claim 1, wherein the material having a corundum-type crystal structure contains α-Cr₂O₃ or an α-Cr₂O₃ solid solution.

9. The base substrate according to claim 1, further comprising a support substrate on a side opposite to a side used for crystal growth of the orientation layer.

10. The base substrate according to claim 9, wherein the support substrate is a sapphire substrate.
